(19) United States
(12) Patent Application Publication
(10) Pub. No.: US 2026/0057149 A1
(43) Pub. Date: Feb. 26, 2026

(54) CONSTRAINED HIERARCHICAL GENERALIZED LINEAR MODEL

(71) Applicant: Deloitte Development LLC, Hermitage, TN (US)

(72) Inventors: Tao Hu, New Albany, OH (US); Shashwati Soumya Swain, Cuttack (IN); Erin Elizabeth Haswell, Portland, OR (US); Charles Alfonso Perez Pelaez, Lima (PE); Matthew McCracken Simms, Santa Cruz, CA (US); Hasim Surel, Miami, FL (US); Satadeep Sinha, Bangalore (IN); Eli Michael Dow, Pleasant Valley, NY (US); Pedro Ignacio José Eduardo Montenegro Montori, Miraflores (PE); Kevin King Griest, Lake Oswego, OR (US); Neil Jones, Encinitas, CA (US); Lincon Ahuja, Sangrur (IN); Sabah Sadiq, Chicago, IL (US)

(21) Appl. No.: 18/815,192

(22) Filed: Aug. 26, 2024

(51) Int. Cl. G06F 30/27

(52) U.S. Cl. CPC G06F 30/27

(57) ABSTRACT

Constrained hierarchical generalized linear model is described herein. A method includes obtaining a hierarchical dataset and constructing a first constrained generalized linear model for a top-level group of the hierarchical dataset. Subsequent constrained generalized linear models for lower levels of the hierarchical dataset are constructed iteratively. A real world scenario is modeled using a set of constrained generalized linear models that comprises the first constrained generalized linear model and the subsequent constrained generalized linear models, wherein domain knowledge constrains model parameters of the set of generalized linear models.

### TECHNICAL FIELD

The present disclosure relates to modeling relationships between variables including hierarchical data.

### BACKGROUND

Generalized linear models (GLMs) generalize linear regression by relating predictor variables to the response variables via a link function, where the value of the response variable is a function of a linear combination of predictor variables. Generalized linear models are used to make predictions based on real world data.

### SUMMARY

Provided herein are techniques that enable constrained hierarchical generalized linear models. In some embodiments, a method includes obtaining a hierarchical dataset associated with a real world scenario comprising observed events, wherein the hierarchical dataset comprises observations derived from the observed events. The method also includes constructing a first constrained generalized linear model for a top-level group of the hierarchical dataset, wherein the generalized linear model models relationships among a response variable and predictor variables extracted from the observations. The method also includes constructing subsequent constrained generalized linear models for lower levels of the hierarchical dataset iteratively, where through regularization, model parameters fitted for lower-level groups are model parameters corresponding to higher-level groups. The method also includes modeling the real world scenario using a set of constrained generalized linear models that comprises the first constrained generalized linear model and the subsequent constrained generalized linear models, wherein domain knowledge constrains model parameters of the set of generalized linear models.

In some embodiments, a system includes at least one processor and at least one memory storing instructions thereon that, when executed by the at least one processor, cause the at least one processor to obtain a hierarchical dataset associated with a real world scenario comprising observed events, wherein the hierarchical dataset comprises observations derived from the observed events. The instructions cause the processor to construct a first constrained generalized linear model for a top-level group of the hierarchical dataset, wherein the generalized linear model models relationships among a response variable and predictor variables extracted from the observations. The instructions cause the processor to construct subsequent constrained generalized linear models for lower levels of the hierarchical dataset iteratively, where through regularization, model parameters fitted for lower-level groups are model parameters corresponding to higher-level groups. The instructions cause the processor to model the real world scenario using a set of constrained generalized linear models that comprises the first constrained generalized linear model and the subsequent constrained generalized linear models, wherein domain knowledge constrains model parameters of the set of generalized linear models.

In some embodiments, at least one non-transitory storage media stores instructions that, when executed by at least one processor, cause the at least one processor to obtain a hierarchical dataset associated with a real world scenario comprising observed events, wherein the hierarchical dataset comprises observations derived from the observed events. The instructions cause the processor to construct a first constrained generalized linear model for a top-level group of the hierarchical dataset, wherein the generalized linear model models relationships among a response variable and predictor variables extracted from the observations. The instructions cause the processor to construct subsequent constrained generalized linear models for lower levels of the hierarchical dataset iteratively, where through regularization, model parameters fitted for lower-level groups are model parameters corresponding to higher-level groups. The instructions cause the processor to model the real world scenario using a set of constrained generalized linear models that comprises the first constrained generalized linear model and the subsequent constrained generalized linear models, wherein domain knowledge constrains model parameters of the set of generalized linear models.

In some embodiments, a mapping of the hierarchical dataset is established to denote relationships between groups across adjacent levels.

In some embodiments, a regularization term is applied to the first generalized linear model and the subsequent generalized linear models.

In some embodiments, the regularization term enforces the model parameters for lower-levels groups to closely align to parameters learned from a level above, wherein the model parameters learned from higher-level groups are fixed effects parameters for lower level groups, anchoring the random effects parameters learned at the lower level with nested groups.

In some embodiments, the fitting of constrained GLM parameters for each group at each level is independent and is processed in parallel.

In some embodiments, domain knowledge is translated into constraints and model parameters fitted through constrained optimization.

In some embodiments, a group is a corresponding higher-level group with respect to a lower-level group when the lower-level group belongs or is nested within the corresponding higher-level group.

The details of one or more embodiments of the invention are set forth in the accompanying drawings and descriptions below. Other features, objects and advantages of the invention will be apparent from the description and drawings, and from the claims.

### DESCRIPTION OF DRAWINGS

FIG. 1 illustrates the nested structure of the input data.

FIG. 2 shows a flow diagram that depicts a sequential parameter optimization process for hierarchical generalized linear models; and

FIG. 3 is a block diagram of a process that enables constrained hierarchical generalized linear models.

FIG. 4 is a block diagram of an example computer system that enables constrained hierarchical generalized linear models.

Like reference symbols in the various drawings indicate like elements.

### DETAILED DESCRIPTION

Embodiments described herein enable a constrained hierarchical generalized linear model (HGLM). In some embodiments, a hierarchical dataset is obtained. The hierarchical dataset includes observations organized into nested groups or clusters. A first Generalized Linear Model (GLM) is learned for a first, top-level group of the hierarchical dataset. A respective GLM is constructed for each remaining group of the hierarchical dataset and fitted with a regularization term, where parameters learned for a higher-level group of the hierarchical dataset are fixed effects parameters for groups at a current level. Respective GLMs are iteratively constructed for each remaining group in a top-down order.

The present techniques enable evaluations of real world scenarios using a constrained hierarchical generalized linear model. The constrained hierarchical generalized linear model simultaneously evaluates relationships within and between levels of grouped hierarchical datasets, making the constrained hierarchical generalized linear model more efficient at accounting for variance among variables at different levels when compared with other hierarchical generalized linear models and generalized linear models. The constrained hierarchical generalized linear model is constructed by fitting regularized GLM parameters for each group at each level independently, in parallel with other groups of the same level, increasing computational efficiency when compared with generalized linear models. Moreover, the constrained hierarchical generalized linear model integrates domain knowledge into constraints on model parameters, such that there is an improved accuracy of conclusions drawn using the model, avoiding false positives and false negatives.

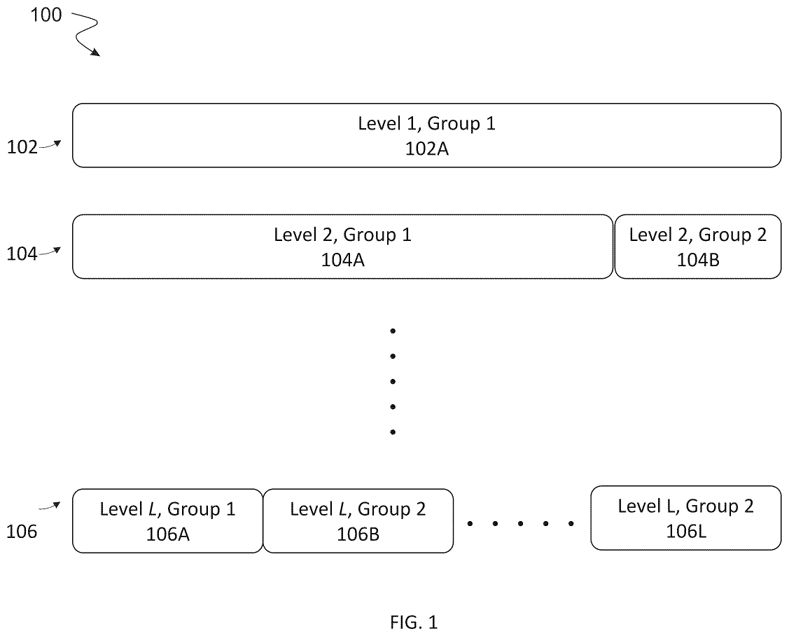

FIG. 1 shows a nested structure of a hierarchical dataset 100. In a hierarchical dataset, nested data exists at more than one level. The hierarchical dataset includes observations that are occurrences of measured values. People, places, and things exist within organizational structures. People are often grouped into families, peer groups, grade levels, education levels, business organizations, social organizations, and the like. Places are often grouped into neighborhoods, cities, states, countries, and the like. Things, such as products offered for sale by retailers can be grouped into nested product categories. For example, a retailers may categorize tennis shoes in a nested structure, where tennis shoes are categorized as athletic shoes. In this examples, athletic shoes can be further categorized as shoes. Thus, tennis shoes belongs to the athletic shoe group, and the athletic shoe group belongs to the shoe group.

FIG. 1 shows a hierarchical dataset 100. In the hierarchical dataset 100, a first level 102 represents the topmost level in the hierarchical dataset with a single group 102A of data. The next level 104 includes a first group 104A and a second group 104B. The groups 104A and 104B of level 104 include data from the single group 102A, further divided into respective groups. For each next level down the hierarchical dataset 101, data from the group(s) of the prior level is divided into groups of increasing granularity to the bottommost level in the hierarchical dataset 100. The final level 106 represents the bottommost level in the hierarchical dataset 100 with data divided into groups 106A . . . 106L.

Continuing the example of shoes, the first level 102 represents the topmost level in the hierarchical dataset with a single group 102A of data corresponding to all shoes. The next level 104 includes a first group 104A and a second group 104B. In examples, first group 104A corresponds to athletic shoes, and a second group 104B dress shoes. The groups 104A and 104B of level 104 include shoes from the single group 102A, further divided into respective groups. For each next level down the hierarchical dataset 101, data from the group(s) of the prior level is divided into groups of increasing granularity to the bottommost level in the hierarchical dataset 100. The final level 106 represents the bottommost level in the hierarchical dataset 100 with data divided into groups 106A . . . 106L. In an example, group 106A corresponds to tennis shoes.

The block diagram of FIG. 1 is not intended to indicate that the hierarchical dataset 100 is to include all of the components shown in FIG. 1. Rather, the hierarchical dataset 100 can include fewer or additional components not illustrated in FIG. 1 (e.g., additional groups, levels, observations, etc.). The hierarchical dataset 100 may include any number of additional components not shown, depending on the details of the specific implementation.

A constrained hierarchical generalized linear model is used to analyze data with a hierarchical or nested structure, such as the hierarchical dataset 100. These constrained hierarchical generalized linear models accurately model dependencies and variability across multiple levels within the data hierarchy. Constrained hierarchical generalized linear model prove particularly invaluable in scenarios where data can be organized into nested groups or clusters. They excel in modeling relationships and variations at each hierarchical tier, effectively navigating potential correlations or dependencies among observations within the same group.

Consider, for example, modeling the price elasticity of demand as the dependence of product demands on respective product prices. In this example, sales data for certain products may exhibit a truncated sales history or minimal price variations. Here, a constrained HGLM leverages product hierarchies, wherein similar products are categorized by retailers in a hierarchical structure, with observations that exist at multiple levels. In the example of tennis shoes, a tennis shoe is considered the lowest level of granularity. At a higher level, tennis shoes are grouped with athletic shoes. At an even higher level, tennis shoes are grouped with shoes. By exploring these hierarchical structures, constrained hierarchical generalized linear models unveil potential correlations, significantly enhancing the accuracy of modeling price elasticity. In some embodiments, the model is used to determine a price of a good or service in the real world moment to moment. In some embodiments, the model is used to place a good or service in the real world relative to a target audience. Accordingly, modeling the real world scenario enables more accurate, informed actions in the real world.

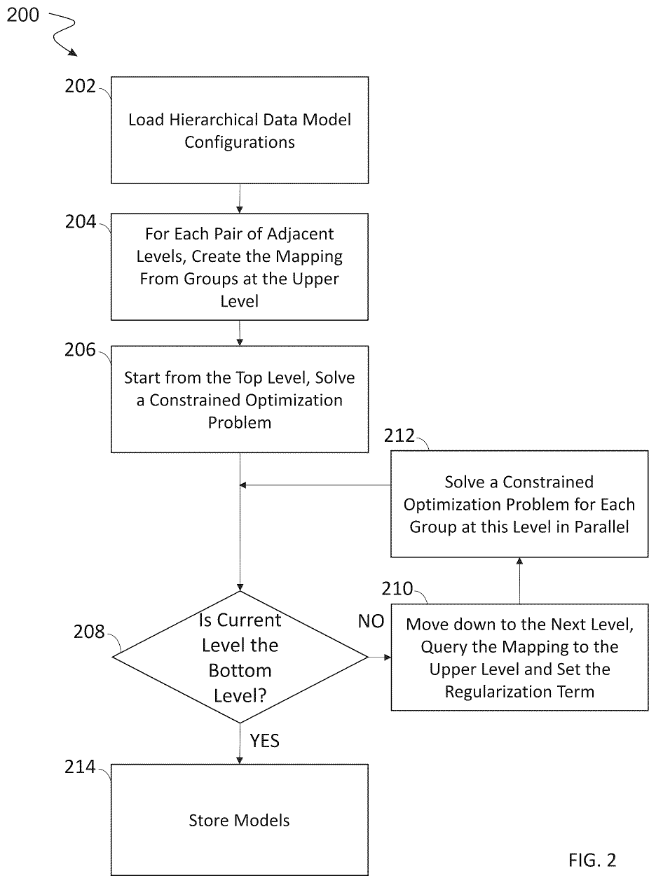

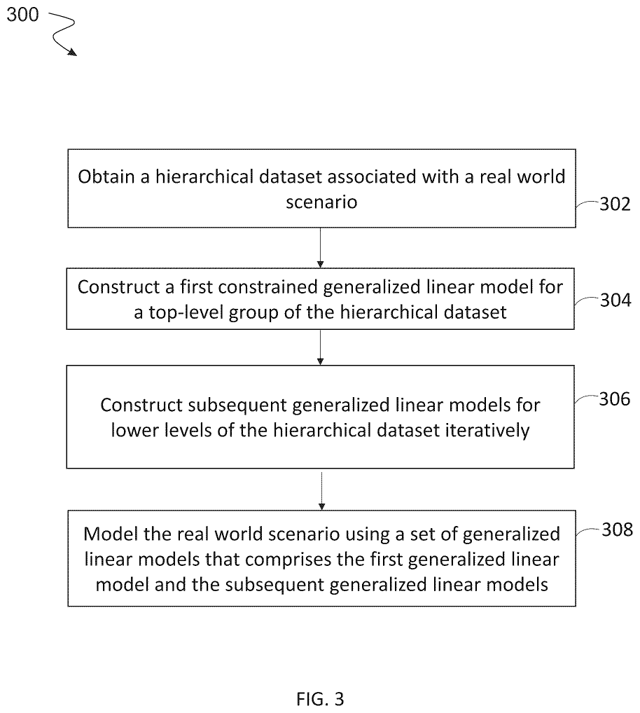

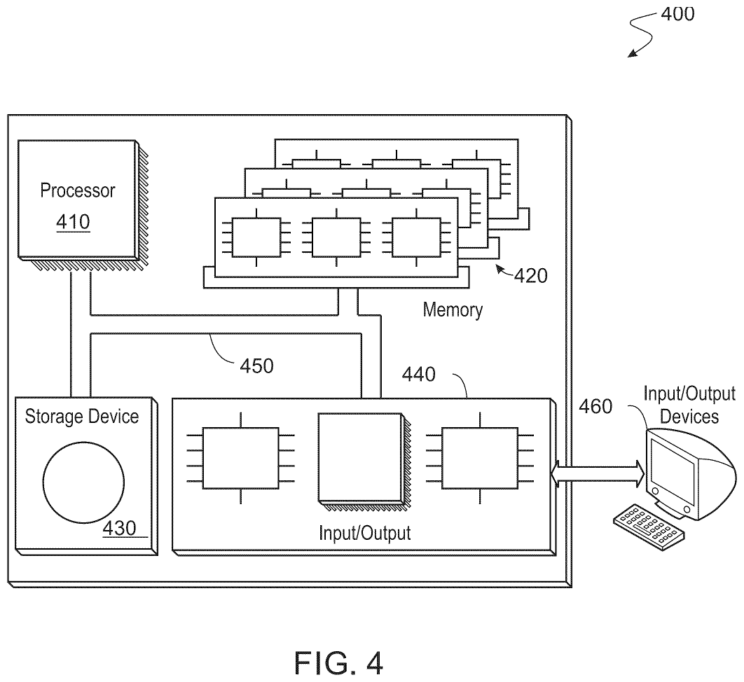

FIG. 2 shows a flow diagram of a process 200 for sequential parameter optimization when constructing constrained hierarchical generalized linear models. In examples, the process 200 executes using a device that is the same as or substantially similar to the system 400 of FIG. 4. In examples, the process 200 of FIG. 2 includes the process 300 of FIG. 3.

At block 202, hierarchical dataset and model configurations are obtained. Model configurations include, for example, values of regularization parameters, regularization function, constraints for the model parameters, link function, and loss function. In examples, the hierarchical dataset is similar to or the same as hierarchical dataset 100 of FIG. 1.

At block 204, for each pair of adjacent levels, a mapping is created from groups at the lower level to groups at the upper level. In examples, the mapping registers each subgroup at a lower level to the overarching group it belongs to at a higher level.

At block 206, starting from the top level, a constrained optimization problem is solved for each level. In examples, the constrained optimization problem is as follows:

$${β}_{1 , 1} = {arg min}_{β} {\sum }_{κ = 1}^{{K}_{1 , 1}} [ ℂ ( [ 1 , {x}_{1 , 1 , κ} ] \cdot {β}_{1 , 1} , ℱ ( {y}_{1 , 1 , κ} ) ) + {λ}_{1 , 1} ψ ( β , 0 ) ] \qquad EQ . 1$$

$$such that$$

$${φ}_{1 , 1 , i} ( β ) \leq 0 for each i ∈ \{ 1 , 2 , … , {N}_{1 , 1} \}$$

where β represents the model parameters, [symbol] is the loss function, x represents predictor variables, y represents response variables, λ≥0, is a regularization parameter, ψ is the regularization term, φ is the constraint function, and [symbol] is the link function. In examples, the constraint function can be specified as φ(β)=β≤0, which enforces β to be non-positive, and the link function can take the logarithmic form as ln(⋅). This level is indexed as level 1, with only one group identified as group 1, as indicated by the parameter subscripts. At this level, there are K_{1,1} data samples and N_{1,1} constraints. As illustrated in Equation 2, except for the top level, the regularization functions compel the model parameters fitted for lower-level groups to closely align with those of the overarching groups they belong to at higher levels. This process effectively enforces hierarchical dependencies.

Beginning with the topmost level of the hierarchical dataset, a single constrained GLM is constructed for this group. In particular, the model parameters β are fitted to capture the average effects of independent variables on the dependent variable and resemble the group-level fixed effects parameters for the entire dataset. At block 208, a determination is made on if the bottommost level of hierarchical dataset has been evaluated. If the bottommost level has been evaluated, process flow continues to block 214 where the model is completed. If the bottommost level has not been evaluated, process flow continues to block 210.

At block 210, the next level in the hierarchical dataset is selected. For each group at this level, the mapping is queried to the upper level and the regularization term for the current selected level is set as follows:

$${β}_{ℓ , ℊ} = {arg min}_{β} {\sum }_{κ = 1}^{{K}_{ℓ , ℊ}} [ ℂ ( [ 1 , {x}_{ℓ , ℊ , κ} ] \cdot {β}_{ℓ , ℊ} , ℱ ( {y}_{ℓ , ℊ , κ} ) ) + {λ}_{ℓ , ℊ} ψ ( β , {β}_{ℓ - 1 , {ℊ}^{′}} ) ] \qquad EQ . 2$$

$$s . t . {φ}_{ℓ , ℊ , i} ( β ) \leq 0 for each i ∈ \{ 1 , 2 , … , {N}_{ℓ , ℊ} \}$$

where [symbol] and [symbol] are the level and group indexes respectively. Accordingly, querying the mapping identifies, for each group at the lower level, a group at the upper level to which the respective lower level group belongs. For each respective lower level group, set [symbol] in EQ. 2 to be the model parameter for that respective lower level group.

At block 210, the analysis moves down to the next level of the hierarchical dataset with increased granularity and/or more groups. A separate GLM is fitted for each group at this level as shown by the equation above. To leverage information from samples in other groups while capturing variability across groups, the GLM is fitted with a regularization term ( [symbol] ). This regularization enforces that the learned model parameters for each group are close to the parameters learned from the level above. For example, in EQ. 2, the regularization term ¿ penalizes discrepancies between the model parameters of a subgroup and those of its encompassing group at a higher level, thereby compelling these two parameter sets to converge closely. A regularization term ψ(β, [symbol] ), such as the Tikhonov regularizer, can be used, and the closeness between model parameter sets across adjacent levels is controlled by a regularization parameter that can be fine-tuned through cross-validation. The process entails dividing the dataset into several subsets. The model undergoes training on one subset (the training set) and subsequent evaluation on a distinct subset (the validation set) across various regularization parameters. The regularization parameter yielding the highest accuracy on the validation set is then selected as the final choice. At block 212, the optimization problem EQ. 2 is solved for each group of the current level, in parallel. After the optimization problem has been solved for each group of the current level, process flow returns to block 108.

The HGLM includes fixed effects and random effects. Fixed effects represent population-level relationships between predictors and the response variable, offering insights into overarching trends and relationships applicable to all groups within the dataset. Random effects capture the variability among different groups or clusters within the hierarchy. Random effects account for the fact that observations within the same group tend to resemble each other more than observations in other groups. Traditionally, HGLM parameters are estimated through maximum likelihood estimation (MLE) or Bayesian methods. MLE provides simultaneous estimation of fixed and random components by maximizing the likelihood function of the data. However, traditional HGLM parameters do not incorporate domain knowledge present in real world scenarios. Fully Bayesian estimation can incorporate some domain knowledge into a hierarchical scheme of prior probabilities, which are combined with likelihood probabilities similar to MLE, to determine posterior distributions of the parameters. However, as the hierarchical structure becomes more complex, the computational complexity of estimating model parameters escalates. Estimating random effects and covariance structures in HGLMs can become computationally intensive, especially when dealing with large datasets. Additionally, deriving the posterior distribution can be intractable for many realistic cases. In cases where priors are conjugate to the likelihood functions and posterior distributions can be derived analytically, these priors often fail to capture complex relationships among parameter values in real-world applications, including domain knowledge. Traditionally, for complex cases, sampling techniques such as Markov Chain Monte Carlo (MCMC) are employed to estimate posterior distributions, which can be computationally expensive or even infeasible.

As shown in FIG. 2, the present techniques deconstruct the joint HGLM parameter estimation problem into sequential parameter estimation for respective levels of the hierarchical dataset, progressing down the hierarchical dataset to more granular levels. The bottom level represents a desired level of granularity. The sequential parameter estimation commences at the top of the hierarchical dataset, treating the entire dataset as a single group and learning a single GLM for this group. Multiple GLMs are fit for lower levels of the hierarchical dataset until the bottommost level of the hierarchical dataset is analyzed. For the analysis of each level, the model parameters learned at the higher level (e.g. [symbol] in EQ. 2) serve as “fixed effects” parameters for the groups at that level, anchoring the “random effects” (captured by the difference between [symbol] and [symbol] in EQ. 2) to be learned at the lower level with nested groups through regularization. This approach yields a set of GLMs with increasing group specificity throughout the hierarchical dataset, and it facilitates the top-down propagation of shared information among related groups. A significant advantage of the sequential parameter estimation is that, instead of optimizing a large parameter space, it solves a sequence of smaller optimization problems, each with increased complexity but in a highly regularized search space. In examples, the constrained search space, due to regularization, entails seeking model parameters for the specific group under analysis within the proximity of the model parameters associated with the overarching group to which it belongs. With the exception of the top level, the fitting of regularized GLM parameters for each group at each level is independent and can be processed in parallel, thereby enhancing computational efficiency.

In embodiments, the present techniques incorporate domain knowledge into the fitting of HGLM parameters. Domain knowledge is translated into constraints on model parameters and employs constrained optimization to determine optimal parameters. For instance, when examining demand price elasticity, there is an inverse correlation between price and demand. Consequently, the price elasticity will invariably manifest a negative value. This understanding serves as a critical business insight, consequently establishing the necessity for negative constraints ( [symbol] <0) when fitting the price elasticity parameters within the model. Typically, constraints are applied at the bottom level of the data hierarchy to generate desired outputs. However, additional constraints can be added at other levels as needed. Unlike the intractable posterior estimation of HGLM parameters resulting from complex domain knowledge in full Bayesian methods, the constrained optimization framework offers a flexible way to incorporate a wide range of complex constraints, including relative constraints on parameter values.

FIG. 3 is a process flow diagram of a process 300 that enables constrained hierarchical generalized linear models. In examples, the process 300 executes using a device that is the same as or substantially similar to the system 400 of FIG. 4. In examples, the process 300 of FIG. 3 includes the process 200 of FIG. 2.

At block 302, a hierarchical dataset is obtained. The hierarchical dataset includes observations organized into nested groups or clusters. In examples, the hierarchical dataset is associated with a real world scenario comprising observations. In examples, the real world scenario is a sequence of events, where observations occur during the sequence of events. For example, people, places, and things are associated with observations, such as measurements, customs, rules, laws, conditions, or other information. In some embodiments, the observations are automatically collected from the environment. For example, observations are automatically captured that group people into families, peer groups, grade levels, education levels, business organizations, social organizations, and the like. In examples, observations are automatically captured that group places into neighborhoods, cities, states, countries, and the like. Additionally, in examples observations are automatically captured that group things, such as products offered for sale by retailers, into nested product categories. Accordingly, in some embodiments nested or hierarchical data is automatically captured from the real-world or environment.

At block 304, a first constrained Generalized Linear Model (GLM) is constructed for a first, top-level group of the hierarchical dataset. In examples, the generalized linear model models relationships among a response variable and predictor variables extracted from the observations.

At block 306, subsequent constrained generalized linear models for lower levels of the hierarchical dataset are constructed iteratively. In examples, regularization, causes model parameters fitted for lower-level groups to be closely aligned with model parameters of corresponding higher-level groups. In examples, a group is a corresponding higher-level group with respect to a lower-level group when the lower-level group belongs or is nested within the higher-level group. In some embodiments, model parameters learned for a higher-level group of the hierarchical dataset resemble fixed effects parameters for groups at a current level that is lower than the higher-level group. Respective generalized linear models are iteratively learned for each remaining group in a top-down order.

At block 308, the real world scenario is modeled using a set of constrained generalized linear models that comprises the first constrained generalized linear model and the subsequent constrained generalized linear models. In examples, the constrained hierarchical generalized linear model is a set of generalized linear models that includes the first generalized linear model and the subsequent generalized linear models, wherein domain knowledge constrains parameters of the set of generalized linear models. In some embodiments, the model is executed to generate predictions on future observations, response variables, predictor variables, or any combinations thereof. For example, people, places, and things associated with observations are used to predict future observations. The model enables testing of variables extracted from the observations, including variables measured on different scales. Accordingly, the model enables a determination of the best set of variables to use when building a hierarchical generalized linear model, which increases the accuracy predictions made using the model. In some embodiments, the model enables an automatic visualization of the real world scenario, including observations and predicted observations. The visualizations are rendered on a display, such as display 460 of FIG. 4.

The resulting model includes a number of hierarchical GLMs. The model caters to the diverse requirements posed by realistic business use cases. For instance, consider the scenario where HGLM is applied to derive price elasticities from products organized within a product hierarchy. Scalability emerges as a significant challenge, especially when dealing with large retailers housing millions of products. Another complexity arises when integrating business domain knowledge into the modeling system-such as the expectation that direct elasticity is typically smaller than the corresponding cross elasticity. Existing techniques falter in addressing these challenges, either lacking the required capability or exhibiting sluggish convergence. The constrained hierarchical generalized linear models enable a scalable approximate solution coupled with a flexible framework to seamlessly inject business constraints on model parameters. Additionally, the constrained hierarchical generalized linear models efficiently handle large datasets and incorporates domain knowledge seamlessly. In examples, the constrained hierarchical generalized linear model can adapt to domain-specific requirements.

The following algorithm shows the construction of a constrained hierarchical generalized linear model.

Algorithm Constrained Hierarchical Generalized Linear Model

```
Input:
Data hierarchy levels: [symbol]  ∈ {1, 2, ... , L}, ranging from level 1 (the highest or most
general level) to level L (the lowest or most specific level)
Hierarchical structure: at each level [symbol]   , groups [symbol]  , ∈ {1,2, ... , Gₗ }. In each group [symbol]  ,
data elements [symbol]  ∈ [symbol] ^{^{m}}, [symbol]   ∈ [symbol] [symbol]    , being the predictor and response
variable pairs. Each group [symbol]  from lower level − 1 belongs to one and only one group [symbol]
at the higher level .
Regularization parameters: [symbol]  , and Regularization term: e.g. the Tikhonov
$regulation ψ ( {z}_{1} , {z}_{2} ) ≡ {‖ {z}_{1} - {z}_{2} ‖}_{2}^{2}$
Constraints for the model parameters [symbol]  ∈ [symbol] : [symbol]  ( [symbol]   ) ≤ 0 [symbol]   }
Link function: [symbol] [symbol]   )
Loss function: [symbol]  ( [symbol] ] · [symbol]  , [symbol] [symbol]    ))
Output: model parameters [symbol]
  1. At top level [symbol]   = 1, solve
    ${β}_{1 , 1} = {arg min}_{β} {\sum }_{κ = 1}^{{K}_{1 , 1}} [ ℂ ( [ 1 , {x}_{1 , 1 , κ} ] \cdot {β}_{1 , 1} , ℱ ( {y}_{1 , 1 , κ} ) ) + {λ}_{1 , 1} ψ ( β , 0 ) ]$
      s.t. φ_{1,1,i} (β) ≤ 0 for each i ∈ {1 ,2, ... , [symbol]  }
  2. for [symbol]   in {2, 3, ... , L} do
  3. parfor [symbol]   ∈{1, 2, ... , [symbol]  } do
  4.  ${β}_{ℓ , ℊ} = arg {min}_{β} {\sum }_{κ = 1}^{{K}_{ℓ , ℊ}} [ ℂ ( [ L {x}_{ℓ , ℊ , κ} ] \cdot {β}_{ℓ , ℊ , κ} , ℱ ( {y}_{ℓ , ℊ , κ} ) ) + {λ}_{l , ℊ} ψ ( β , {β}_{ℓ - 1 , ℊ} ′ ) ]$
  5. end parfor
  6. end for
```

FIG. 4 is a block diagram of an example computer system that enables constrained hierarchical generalized linear models. For example, referring to FIG. 1, user space 102, operating system 104, hardware 106, and kernel space 108 could be a part of an example of the system 400 described here. The system 400 includes a processor 410, a memory 420, a storage device 430, and one or more input/output interface devices 440. Each of the components 410, 420, 430, and 440 can be interconnected, for example, using a system bus 450.

The processor 410 is capable of processing instructions for execution within the system 400. The term “execution” as used here refers to a technique in which program code causes a processor to carry out one or more processor instructions. The processor 410 is capable of processing instructions stored in the memory 420 or on the storage device 430. The processor 410 may execute operations such as process memory protection against foreign code injection.

The memory 420 stores information within the system 400. In some implementations, the memory 420 is a computer-readable medium. In some implementations, the memory 420 is a volatile memory unit. In some implementations, the memory 420 is a non-volatile memory unit. The storage device 430 is capable of providing mass storage for the system 400. In some implementations, the storage device 430 is a non-transitory computer-readable medium. In various different implementations, the storage device 430 can include, for example, a hard disk device, an optical disk device, a solid-state drive, a flash drive, magnetic tape, or some other large capacity storage device. In some implementations, the storage device 430 may be a cloud storage device, e.g., a logical storage device including one or more physical storage devices distributed on a network and accessed using a network. The input/output interface devices 440 provide input/output operations for the system 400. In some implementations, the input/output interface devices 440 can include one or more of a network interface devices, e.g., an Ethernet interface, a serial communication device, e.g., an RS-232 interface, and/or a wireless interface device, e.g., an 802.11 interface, a 3G wireless modem, a 5G wireless modem, a 7G wireless modem, etc. A network interface device allows the system 400 to communicate, for example, transmit and receive such data. In some implementations, the input/output device can include driver devices configured to receive input data and send output data to other input/output devices, e.g., keyboard, printer and display devices 460. In some implementations, mobile computing devices, mobile communication devices, and other devices can be used.

A server or database system can be distributively implemented over a network, such as a server farm, or a set of widely distributed servers or can be implemented in a single virtual device that includes multiple distributed devices that operate in coordination with one another. For example, one of the devices can control the other devices, or the devices may operate under a set of coordinated rules or protocols, or the devices may be coordinated in another fashion. The coordinated operation of the multiple distributed devices presents the appearance of operating as a single device.

In some examples, the system 400 is contained within a single integrated circuit package. A system 400 of this kind, in which both a processor 410 and one or more other components are contained within a single integrated circuit package and/or fabricated as a single integrated circuit, is sometimes called a microcontroller. In some implementations, the integrated circuit package includes pins that correspond to input/output ports, e.g., that can be used to communicate signals to and from one or more of the input/output interface devices 440.

Although an example processing system has been described in FIG. 4, implementations of the subject matter and the functional operations described above can be implemented in other types of digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible program carrier, for example a computer-readable medium, for execution by, or to control the operation of, a processing system. The computer readable medium can be a machine readable storage device, a machine readable storage substrate, a memory device, or a combination of one or more of them.

The term “system” may encompass all apparatus, devices, and machines for processing data, including by way of example a programmable processor, a computer, or multiple processors or computers. A processing system can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, executable logic, or code) can be written in any form of programming language, including compiled or interpreted languages, or declarative or procedural languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

Computer readable media suitable for storing computer program instructions and data include all forms of non-volatile or volatile memory, media and memory devices, including by way of example semiconductor memory devices, e.g., EPROM, EEPROM, and flash memory devices; magnetic disks, e.g., internal hard disks or removable disks or magnetic tapes; magneto optical disks; and CD-ROM, DVD-ROM, and Blu-Ray disks. The processor and the memory can be supplemented by, or incorporated in, special purpose logic circuitry. Sometimes a server is a general purpose computer, and sometimes it is a custom-tailored special purpose electronic device, and sometimes it is a combination of these things. Implementations can include a back end component, e.g., a data server, or a middleware component, e.g., an application server, or a front end component, e.g., a client computer having a graphical user interface or a Web browser through which a user can interact with an implementation of the subject matter described is this specification, or any combination of one or more such back end, middleware, or front end components. For example, the functionality described herein may be realized through an application or “app.” The app may be located on a device as described herein. The app may also be located on a second device communicatively coupled with a device as described herein. The components of the system can be interconnected by any form or medium of digital data communication, e.g., a communication network. Examples of communication networks include a local area network (“LAN”) and a wide area network (“WAN”), e.g., the Internet. The components of the system may also communicate via short range wireless communication standard, such as Bluetooth.

A number of embodiments of the invention have been described. Nevertheless, it will be understood that various modifications may be made without departing from the spirit and scope of the invention.

What is claimed is:

1. A method comprising:
obtaining, using at least one hardware processor, a hierarchical dataset associated with a real world scenario comprising observed events, wherein the hierarchical dataset comprises observations derived from the observed events;
constructing, using the at least one hardware processor, a first constrained generalized linear model for a top-level group of the hierarchical dataset, wherein the generalized linear model models relationships among a response variable and predictor variables extracted from the observations;
constructing, using the at least one hardware processor, subsequent constrained generalized linear models for lower levels of the hierarchical dataset iteratively, where through regularization, model parameters fitted for lower-level groups are model parameters corresponding to higher-level groups; and
modeling, using the at least one hardware processor, the real world scenario using a set of constrained generalized linear models that comprises the first constrained generalized linear model and the subsequent constrained generalized linear models, wherein domain knowledge constrains model parameters of the set of generalized linear models.

2. The method of claim 1, wherein a mapping of the hierarchical dataset is established to denote relationships between groups across adjacent levels.

3. The method of claim 1, wherein a regularization term is applied to the first generalized linear model and the subsequent generalized linear models.

4. The method of claim 3, wherein the regularization term enforces the model parameters for lower-levels groups to closely align to parameters learned from a level above, wherein the model parameters learned from higher-level groups are fixed effects parameters for lower level groups, anchoring random effects parameters learned at the lower level with nested groups.

5. The method of claim 1, wherein the fitting of constrained GLM parameters for each group at each level is independent and is processed in parallel.

6. The method of claim 1, comprising translating domain knowledge into constraints and fitting model parameters through constrained optimization.

7. The method of claim 1, wherein a group is a corresponding higher-level group with respect to a lower-level group when the lower-level group belongs or is nested within the corresponding higher-level group.

8. A system, comprising:
at least one processor; and
at least one memory storing instructions thereon that, when executed by the at least one processor, cause the at least one processor to:
obtain a hierarchical dataset associated with a real world scenario comprising observed events, wherein the hierarchical dataset comprises observations derived from the observed events;
construct a first constrained generalized linear model for a top-level group of the hierarchical dataset, wherein the generalized linear model models relationships among a response variable and predictor variables extracted from the observations;
construct subsequent constrained generalized linear models for lower levels of the hierarchical dataset iteratively, where through regularization, model parameters fitted for lower-level groups are model parameters corresponding to higher-level groups; and
model the real world scenario using a set of constrained generalized linear models that comprises the first constrained generalized linear model and the subsequent constrained generalized linear models, wherein domain knowledge constrains model parameters of the set of generalized linear models.

9. The system of claim 8, wherein a mapping of the hierarchical dataset is established to denote relationships between groups across adjacent levels.

10. The system of claim 8, wherein a regularization term is applied to the first generalized linear model and the subsequent generalized linear models.

11. The system of claim 10, wherein the regularization term enforces the model parameters for lower-levels groups to closely align to parameters learned from a level above, wherein the model parameters learned from higher-level groups are fixed effects parameters for lower level groups, anchoring random effects parameters learned at the lower level with nested groups.

12. The system of claim 8, wherein the fitting of constrained GLM parameters for each group at each level is independent and is processed in parallel.

13. The system of claim 8, comprising translating domain knowledge into constraints and fitting model parameters through constrained optimization.

14. The system of claim 8, wherein a group is a corresponding higher-level group with respect to a lower-level group when the lower-level group belongs or is nested within the corresponding higher-level group.

15. At least one non-transitory storage media storing instructions that, when executed by at least one processor, cause the at least one processor to:
obtain a hierarchical dataset associated with a real world scenario comprising observed events, wherein the hierarchical dataset comprises observations derived from the observed events;
construct a first constrained generalized linear model for a top-level group of the hierarchical dataset, wherein the generalized linear model models relationships among a response variable and predictor variables extracted from the observations;
construct subsequent constrained generalized linear models for lower levels of the hierarchical dataset iteratively, where through regularization, model parameters fitted for lower-level groups are model parameters corresponding to higher-level groups; and
modeling the real world scenario using a set of constrained generalized linear models that comprises the first constrained generalized linear model and the subsequent constrained generalized linear models, wherein domain knowledge constrains model parameters of the set of generalized linear models.

16. The at least one non-transitory storage media of claim 15, wherein a mapping of the hierarchical dataset is established to denote relationships between groups across adjacent levels.

17. The at least one non-transitory storage media of claim 15, wherein a regularization term is applied to the first generalized linear model and the subsequent generalized linear models.

18. The at least one non-transitory storage media of claim 17, wherein the regularization term enforces the model parameters for lower-levels groups to closely align to parameters learned from a level above, wherein the model parameters learned from higher-level groups are fixed effects parameters for lower level groups, anchoring random effects parameters learned at the lower level with nested groups.

19. The at least one non-transitory storage media of claim 15, wherein the fitting of constrained GLM parameters for each group at each level is independent and is processed in parallel.

20. The at least one non-transitory storage media of claim 15, comprising translating domain knowledge into constraints and fitting model parameters through constrained optimization.
